(19) United States
(12) Patent Application Publication
(10) Pub. No.: US 2025/0328064 A1
(43) Pub. Date: Oct. 23, 2025

(54) MICRO PROJECTOR AND SEMICONDUCTOR WAFER

(71) Applicant: JADE BIRD DISPLAY (SHANGHAI) LIMITED, SHANGHAI (CN)

(72) Inventor: Chenchao XU, Shanghai (CN)

(21) Appl. No.: 19/182,779

(22) Filed: Apr. 18, 2025

(30) Foreign Application Priority Data
Apr. 18, 2024 (WO) PCT/CN2024/088548

(51) Int. Cl. G03B 21/20; G02B 7/02; H10H 29/24

(52) U.S. Cl. CPC G03B 21/208; G02B 7/021; G03B 21/2033; H10H 29/24

(57) ABSTRACT

A micro projector and a semiconductor wafer are provided. The micro projector includes a micro LED array display chip; and a lens group provided above the micro LED array display chip and supported by a bottom connector. The semiconductor wafer includes a micro LED wafer including a plurality of micro LED array display chips; and a plurality of lens wafers stacked on the micro LED wafer to form a micro projector array.

### CROSS-REFERENCE TO RELATED APPLICATIONS

The present disclosure claims the benefits of priority to PCT Application No. PCT/CN2024/088548, filed on Apr. 18, 2024, which is incorporated herein by reference in its entirety.

### TECHNICAL FIELD

The present disclosure generally relates to micro display technology, and more particularly, to a micro projector and a semiconductor wafer.

### BACKGROUND

Micro LEDs (light emitting diodes) with extra small area and higher resolution are increasingly popular.

A micro LED display chip with a micro LED display array can be used to form various kinds of devices, such as camera modules, projection modules, display modules, VR/AR (Virtual Reality/Augmented Reality) optical modules, and the like.

A conventional micro projector includes a micro LED display chip for displaying an image or video, and a lens group for adjusting and transmitting the light of the image or video. A lens package structure and a base are further provided to support the lens group and to assemble the micro projector as a whole.

### SUMMARY OF THE DISCLOSURE

Embodiments of the present disclosure include a micro projector. The micro projector includes a micro LED array display chip; and a lens group provided above the micro LED array display chip and supported by a bottom connector.

Embodiments of the present disclosure also include a semiconductor wafer. The semiconductor wafer includes a micro LED wafer including a plurality of micro LED array display chips; and a plurality of lens wafers stacked on the micro LED wafer to form a micro projector array.

Many advantages and features of the present disclosure will be further understood from the following detailed description and the appended drawings.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 a structural diagram showing an exemplary micro projector, according to some embodiments of the present disclosure.

FIG. 2 illustrates a structural diagram showing a side view of an exemplary configuration of a micro LED array display chip, according to some embodiments of the present disclosure.

FIG. 3 illustrates a structural diagram showing a side sectional view of the micro LED array display chip shown in FIG. 2, according to some embodiments of the present disclosure.

FIG. 4 illustrates a structural diagram showing a variant of a lens group of the exemplary micro projector, according to some embodiments of the present disclosure.

FIG. 5 illustrates a structural diagram showing a top view of the micro projector shown in FIG. 1, according to some embodiments of the present disclosure.

FIG. 6 illustrates a structural diagram showing a semiconductor wafer including a micro projector array, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

For a conventional micro projector, a diameter of a lens group is much larger than a micro LED display panel for effectively transmitting light of an image or video. Therefore, the volume of the micro projector is increased. Additionally, a lens package structure needs to be assembled with a base without connecting to the display panel, which may further increase the volume of the projector. Moreover, due to the structure of the lens groups, the lens package structure is complex, which increases fabrication cost and process difficulty. Because of a large distance between each lens of the lens group, light loss of the micro display panel may decrease final image quality.

Furthermore, the micro LED display panel usually includes a display chip and a chip package. The chip package further increases the volume of the micro projector and generates light loss of the projector.

To fabricate the micro projector, the plurality of lens of the lens group need to be further aligned with the micro LED display panel, which further increases the difficulty and fabrication cost. The production yield depends on an adopted packaging process and structure. In addition, downsizing projectors in height and volume is generally desired, which can expand application scope of the projector.

Some embodiments of the present disclosure provide a micro projector with a compact structure, which may improve the fabrication process and decrease the cost.

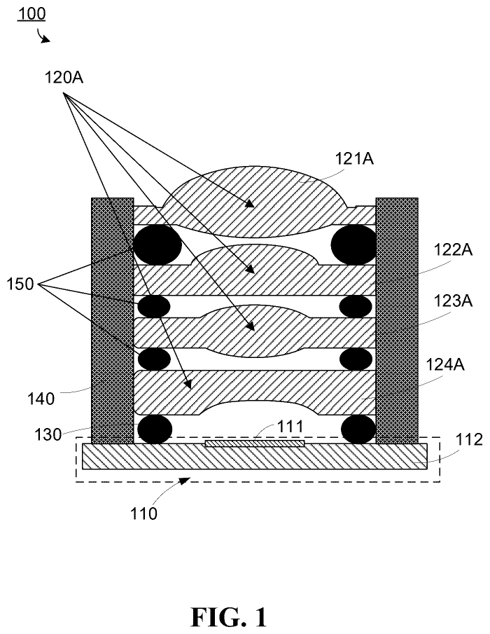

FIG. 1 is a structural diagram showing an exemplary micro projector 100, according to some embodiments of the present disclosure. As shown in FIG. 1, micro projector 100 includes a micro LED array display chip 110 and a lens group 120A. Lens group 120A is provided above micro LED array display chip 110 and is supported by a bottom connector 130. Bottom connector 130 is configured to connect micro LED array display chip 110 and lens group 120A.

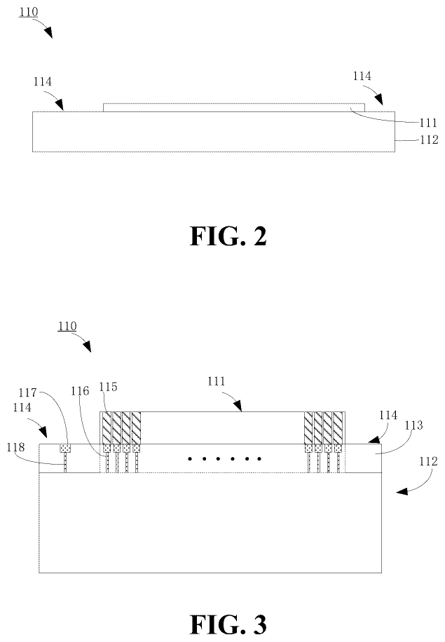

FIG. 2 illustrates a structural diagram showing a side view of an exemplary configuration of micro LED array display chip 110, according to some embodiments of the present disclosure. As shown in FIG. 2, micro LED array display chip 110 includes a micro LED array area 111, a non-functional area 114, and an IC (integrated circuit) backplane 112. Micro LED array area 111 is located on IC backplane 112 to form an image display area of the micro LED array display chip 110. The rest of the area on IC backplane 112 not covered by micro LED array area 111 is formed as non-functional area 114. In some embodiments, micro LED array display chip 110 is a self-emitting micro LED display panel.

FIG. 3 illustrates a structural diagram showing a side sectional view of the micro LED array display chip 110 shown in FIG. 2, according to some embodiments of the present disclosure. Referring to FIG. 3, IC backplane 112 is formed at the bottom of micro LED array area 111 with an extended part extending outside of micro LED array area 111. Micro LED array area 111 further includes a plurality of micro LEDs 115 which are provided in an array. A plurality of signal metal pads and dummy metal can be further formed on a surface of the non-functional area 114. The signal metal pads can include a plurality of IO (input/output) metal pads 117 and a plurality of dummy metal pads (not shown).

IO metal pads 117 can conductively connect to IC backplane 112. Micro LEDs 115 in the micro LED array area 111 are connected with IC backplane 112 by a plurality of first metal connected holes 116, respectively. That is, every micro LED 115 is connected with IC backplane 112 by one first metal connected hole 116. Respective tops of first metal connected holes 116 are connected with micro LEDs 115 one-to-one. Accordingly, the plurality of first metal connected holes 116 correspond to the plurality of micro LEDs 115. The first metal connected holes 116 are formed as a first connected area on IC backplane 112, which corresponds to micro LED array area 111 (i.e., the image display area). Bottoms of the signal metal pads, i.e., IO metal pads 117 and the dummy metal pads, are connected with IC backplane 112 by a plurality of second metal connected holes 118. Bottoms of second metal connected holes 118 of IO metal pads 117 are conductively connected with bottoms of first metal connected holes 116. Therefore, IO metal pads 117 can conductively connect with micro LEDs 115 through second metal connected holes 118, IC backplane 112, and first metal connected holes 116. The second metal connected holes 118 are formed as a second connected area on non-functional area 114. The second connected area is away from the first connected area, and close to the edge of IC backplane 112. In some embodiments, the first connected area refers to an inside connected area, and the second connected area refers to an external connected area. First metal connected holes 116 and second metal connected holes 118 are formed in a top layer 113 of IC backplane 112. It is noted that IC backplane 112 can further include a conventional metal interconnected multilayer to respectively connect IO metal pads 117 for micro LEDs 115. The metal interconnected multilayer can be understood by those skilled in the art, which will not be described herein.

Referring again to FIG. 1, in some embodiments, micro projector 100 further includes a lens barrel 140 provided on micro LED array display chip 110 and around lens group 120A for defining and limiting lens group 120A on micro LED array display chip 110. With lens barrel 140, the position of lens group 120A relative to micro LED array display chip 110 is further fixed in a horizontal direction. In some embodiments, lens barrel 140 is connected to an edge of lens group 120A. A thickness of lens barrel 140 is in a range of 3.5 mm to 8 mm. A material of lens barrel 140 is glass or resin. In some embodiments, lens barrel 140 is adhered to the edge of lens group 120A by glue. In some embodiments, lens barrel 140 is non-transparent, so that the light emitted from micro LED array display chip 110 cannot be transmitted outwards, thereby decreasing the light loss of micro projector 100.

In some embodiments, micro LED array area 111 of micro LED array display chip 110 is packaged or sealed with lens group 120A and lens barrel 140, together with IC backplane 112. With lens group 120A and lens barrel 140, light emitted from micro LED array area 111 can be emitted in parallel. In some embodiments, a bottom of lens barrel 140 is provided on non-functional area 114 of micro LED array display chip 110. For example, the bottom of lens barrel 140 is provided on an edge surface of micro LED array display chip 110. It can be understood that lens barrel 140 forms a closed area on micro LED array display chip 110 (more specifically, on IC backplane 112), and surrounds the image display area (i.e., the micro LED array area 111) and lens group 120A. Therefore, a size of micro projector 100 is not greater than a size of micro LED array display chip 110 in a horizontal dimension. In some embodiments, an outer sidewall of lens barrel 140 is aligned with a sidewall of micro LED array display chip 110 in a vertical direction, which may provide a maximum closed area formed by lens barrel 140. In some embodiments, a top of lens barrel 140 is lower than a top of lens group 120A, so that a height of micro projector 100 is the same as a height of lens group 120A with micro LED array display chip 110, which may minimize the size of micro projector 100 in a vertical dimension.

In some embodiments, lens group 120A includes a plurality of optical lenses stacked in the vertical direction. Referring to FIG. 1, in this example, lens group 120A includes four optical lenses 121A, 122A, 123A, and 124A from top to bottom. The plurality of optical lenses are connected and supported by a connection structure 150 between adjacent optical lenses, and the adjacent optical lenses do not contact to each other. In some embodiments, an optical property of each optical lens is different from that of the other lenses. For example, each optical lens can be a convex lens, a concave lens, a middle biconvex lens, a top biconvex lens, or the like. In this example, the plurality of optical lenses of lens group 120A include a top biconvex lens 121A, a convex lens 122A, a middle biconvex lens 123A, and a concave lens 124A from top to bottom as shown in FIG. 1.

Referring again to FIG. 1, each of the optical lenses of lens group 120A includes a curved portion and a flat portion around the curved portion. The curved portion is configured to transmit image light emitted from micro LED array display chip 110. The flat portion is configured to connect with connection structure 150. Connection structure 150 is configured to connect surfaces of the flat portions of the adjacent optical lenses. The curved portion is at a position corresponding to micro LED array area 111 of micro LED array display chip 110. In some embodiments, a distance between the adjacent flat portions of adjacent optical lenses is not greater than 5 mm.

In some embodiments, a projection area of the curved portion of each optical lens on micro LED array display chip 110 covers micro LED array area 111. That is, a profile of the curved portion projected on micro LED array display chip 110 covers a profile of micro LED array area 111. In some embodiments, the projection area of the curved portion of top-most optical lens 121A is larger than the projection areas of the curved portions of other optical lenses of lens group 120A. That is, the profile of the curved portions of top-most optical lens 121A is the largest one and surrounds the profiles of the curved portions of the other optical lenses 122A-124A. In some embodiments, a center axis of micro LED array area 111 is aligned with a center axis of the curved portion of each optical lens of lens group 120A.

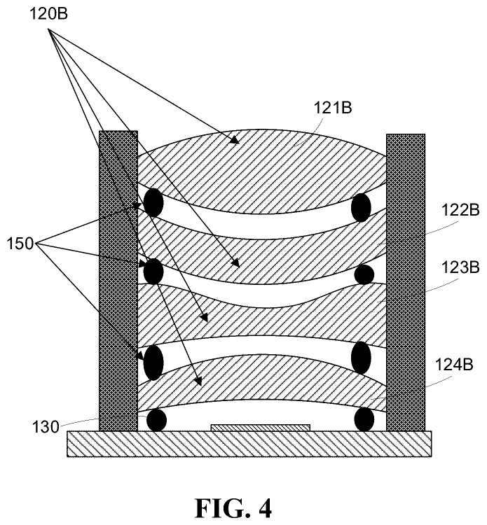

FIG. 4 illustrates a structural diagram showing a variant of a lens group 120B, according to some embodiments of the present disclosure. As shown in FIG. 4, types of four optical lenses 121B, 122B, 123B, and 124B of lens group 120B are different from the types of four optical lenses 121A, 122A, 123A, and 124A of lens group 120A as shown in FIG. 1. In this example, each optical lens (i.e., 121B, 122B, 123B, and 124B) has a curved portion and does not have a flat portion. Connection structures 150 are provided at the periphery of each optical lens. In some embodiments, a center axis of micro LED array area 111 is aligned with center axis of curved portion of each optical lens in lens group 120B. In some embodiments, a material of the optical lenses is resin. A gap between adjacent optical lenses is about 0.2 mm, for example, in a range of 0.1 mm to 0.3 mm. As shown in FIG. 1, a distance between adjacent optical lenses can be varied at different positions. The gap between adjacent optical lenses means a shortest distance between adjacent optical lenses.

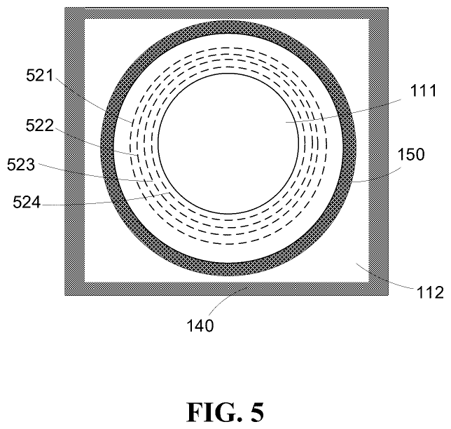

FIG. 5 illustrates a structural diagram showing a top view of micro projector 100 shown in FIG. 1, according to some embodiments of the present disclosure. Referring to FIG. 1 and FIG. 5, the profiles (i.e., profiles 521 to 524) of the curved portions of the optical lenses (i.e., lenses 121A to 124A) projected on micro LED array display chip 110 cover the profile of micro LED array area 111. The projection area of the curved portion of top-most optical lens 121A is larger than the projection areas of the curved portions of the other optical lenses. That is, profile 521 of the curved portions of top-most optical lens 121A is the largest one and surrounds the profiles (i.e., profiles 522 to 524) of the curved portions of other optical lenses (i.e., lenses 122A to 124A).

Referring back to FIG. 1, the top of bottom connector 130 is connected to the bottom-most lens (i.e., lens 124A in this example) of lens group 120A, and a bottom of bottom connector 130 is connected to micro LED array display chip 110. In some embodiments, the bottom of bottom connector 130 is provided on a surface of non-functional area 114. Specifically, bottom connector 130 is provided within the closed area formed by lens barrel 140.

In some embodiments, bottom connector 130 can include a sealant and a plurality of spacers. Bottom connector 130 can be a combination of the sealant and the plurality of spacers. The material of the sealant can comprise one or more of a resin and a polymer. For example, the resin can be an epoxy resin, and the polymer can be silicone. The spacer is rigid. In some embodiments, the spacers can be small balls with the same diameter. Since the sealant is flowable, a diameter of the balls can define a height of bottom connector 130 above non-functional area 114. Using such bottom connector 130, the distance between lens group 120A and micro LED array display chip 110 can be efficiently fixed or adjusted according to the thickness of the spacers (e.g., the diameter of the balls). In some embodiments, the sealant is gasket glue.

In some embodiments, bottom connector 130 can include a light absorption material, such as a combination of a film forming agent composed of resin and polymer and light sensitive sensitizer. The film forming agent can include one or more of resin, polymer, light-sensitive sensitizer, or a combination thereof. With the light absorption material, bottom connector 130 can further absorb the light emitted from the image display area, so as to improve the image quality.

In some embodiments, connection structure 150 can be formed of the same material as bottom connector 130. In some embodiments, the spacers of connection structure 150 for different layers between adjacent optical lens can be different. Therefore, the distances between different adjacent optical lens can be different and can be adjust based on the optical properties of the respective optical lens.

In some embodiments, as show in FIG. 5, a projection of connection structure 150 on micro LED array display chip 110 is a circular ring shape, and a projection of lens barrel 140 on micro LED array display chip 110 is a rectangular or square ring shape. In some embodiments, the projection of connection structure 150 on micro LED array display chip 110 is a rectangular or square ring shape, and the projection of lens barrel 140 on micro LED array display chip 110 is a circular ring shape. In some embodiments, the projection of connection structure 150 on micro LED array display chip 110 and the projection of lens barrel 140 on micro LED array display chip 110 have the same shape, which depends on a design of micro LED array display chip 110. Specifically, in some embodiments, the projection of connection structure 150 on micro LED array display chip 110 and/or projection of lens barrel 140 on micro LED array display chip 110 can be a square ring shape.

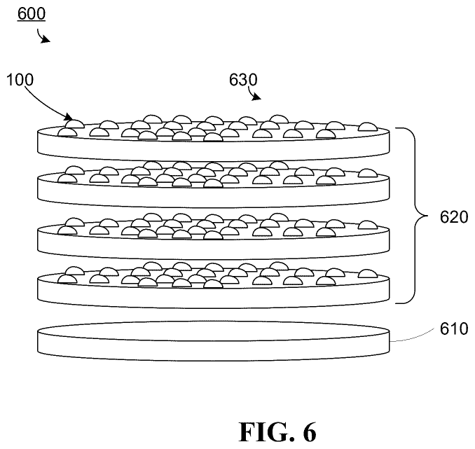

FIG. 6 illustrates a structural diagram showing a semiconductor wafer 600 including a micro projector array, according to some embodiments of the present disclosure. As shown in FIG. 6, semiconductor wafer 600 includes a micro LED wafer 610 and a plurality of lens wafers 620. Micro LED wafer 610 includes a plurality of micro LED array display chips 110 as shown in FIGS. 1 to 5. The plurality of lens wafers 620 are stacked on the micro LED wafer 610. Each lens wafer of the plurality of lens wafers 620 includes a plurality of optical lenses corresponding to the plurality of micro LED array display chips, i.e., one optical lens corresponding to each micro LED array display chip. The stacked micro LED wafer 610 and the plurality of lens wafers 620 form a micro projector array 530. Micro projector array 630 includes a plurality of micro projectors 100 as shown in FIG. 1 to FIG. 5.

Lens wafers 620 are supported by bottom connector 130 and connection structure 150 as described above consistent with FIGS. 1 to 5, and a distance between adjacent lens wafers 620 is defined by connection structure 150. A distance between lens wafers 620 and micro LED wafer 610 is defined by bottom connector 130. Further details of micro projector 100, micro LED array display chips 110, bottom connector 130, and connection structure 150 can be found by referring to the description above with reference to FIGS. 1 to 5, which will not repeat herein.

In some embodiments, semiconductor wafer 600 further includes a cutting pattern for cutting and separating micro projector array 630 into the plurality of individual micro projectors 100.

The micro projector provided by the embodiments of the present disclosure has a more compact structure, which can expand an application scope of the micro projector. The semiconductor wafer provided by the embodiments of the present disclosure can improve the process efficiency for producing the micro projector, thereby reducing the cost.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro projector, comprising:
a micro LED array display chip; and
a lens group provided above the micro LED array display chip and supported by a bottom connector.

2. The micro projector according to claim 1, wherein the bottom connector is configured to connect the lens group and the micro LED array display chip.

3. The micro projector according to claim 2, wherein the micro LED array display chip comprises a micro LED array area for emitting light, and a non-functional area, wherein the bottom connector is provided on the non-functional area.

4. The micro projector according to claim 1, wherein the bottom connector comprises a sealant and a plurality of spacers.

5. The micro projector according to claim 4, wherein the spacer is rigid.

6. The micro projector according to claim 5, wherein the spacer is a ball.

7. The micro projector according to claim 3, wherein the micro projector further comprises a lens barrel provided around the lens group and on the non-functional area of the micro LED array display chip.

8. The micro projector according to claim 7, wherein the lens barrel is connected to an edge of the lens group.

9. The micro projector according to claim 8, wherein the lens barrel is provided on an edge surface of the micro LED array display chip.

10. The micro projector according to claim 7, wherein a surface of the micro LED array area is packaged or sealed by the lens group and the barrel.

11. The micro projector according to claim 7, wherein a top of the lens barrel is lower than a top of the lens group.

12. The micro projector according to claim 3, wherein the lens group comprises:
a plurality of optical lenses stacked from top to bottom without contacting from each other; and
a connection structure provided between adjacent optical lenses of the lens group for connecting and supporting the adjacent optical lens.

13. The micro projector according to claim 12, wherein an optical property of each of the optical lenses is different from optical properties of other ones of the plurality of optical lenses.

14. The micro projector according to claim 12, wherein each optical lens comprises
a curved portion configured to transmit light emitted from the micro LED array display chip; and
a flat portion configured to connect with the connection structure.

15. The micro projector according to claim 14, wherein the connection structure is connected to a surface of the flat portions of the adjacent optical lenses.

16. The micro projector according to claim 14, wherein each curved portion of the plurality of optical lenses corresponds to the micro LED array area of the micro LED array display chip.

17. The micro projector according to claim 16, wherein a projection of the curved portion on the micro LED array display chip covers the micro LED array area.

18. The micro projector according to claim 16, wherein a center axis of the micro LED array area is aligned with a center axis of the curved portion of each optical lens.

19. The micro projector according to claim 17, wherein a projection of the curved portion of a top-most one of the plurality of optical lenses covers a projection of the curved portion of other ones of the plurality of optical lenses.

20. The micro projector according to claim 12, wherein the lens group comprises a top biconvex lens, a convex lens, a middle biconvex lens, and a concave lens from top to bottom.

21. The micro projector according to claim 14, wherein a distance between adjacent flat portions of the adjacent optical lenses is not greater than 5 mm.

22. A semiconductor wafer comprising:
a micro LED wafer comprising a plurality of micro LED array display chips; and
a plurality of lens wafers stacked on the micro LED wafer to form a micro projector array.

23. The semiconductor wafer according to claim 22, wherein the micro projector array comprises a plurality of micro projectors, each micro projector comprising:
a micro LED array display chip; and
a lens group provided above the micro LED array display chip and supported by a bottom connector.

24. The semiconductor wafer according to claim 22, further comprising a connection structure provided between adjacent ones of the lens wafers for connecting and supporting the adjacent lens wafers.

25. The semiconductor wafer according to claim 23, further comprising
a cutting pattern for cutting the micro projector array into the plurality of micro projectors.
